(19) United States
(12) Patent Application Publication
(10) Pub. No.: US 2010/0091808 A1
(43) Pub. Date: Apr. 15, 2010

(54) Semiconductor laser device and manufacturing method therefor

(75) Inventor: Yoshiyuki Takahira, Osaka (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/588,334

(22) Filed: Oct. 13, 2009

(30) Foreign Application Priority Data
Oct. 14, 2008 (JP) 2008-265566

(51) Int. Cl. H01S 5/00; H01L 33/00

(52) U.S. Cl. 372/44.01; 438/26; 257/E33.056

(57) ABSTRACT

Provides a semiconductor laser device, as well as a manufacturing method therefor, capable of solving a problem of yield decreases in a structure for mounting a nitride semiconductor laser element onto a mount member. The nitride semiconductor laser device has a submount 2, and a nitride semiconductor laser element 1 which is mounted on a surface of the submount 2 with a solder 4 so that a nitride semiconductor is exposed from a side face thereof. The solder 4 is positioned between the submount 2 and the nitride semiconductor laser element 1 and has a width W3 smaller than a lateral width W4 of the nitride semiconductor laser element 1.

### TECHNICAL FIELD

The present invention relates to a semiconductor laser device, as well as its manufacturing method, which includes a nitride semiconductor laser element formed from III-V group nitride semiconductor.

### BACKGROUND ART

The nitride semiconductor laser element has been receiving attention as a short-wavelength light source for performing read and write of information on high-density optical recording mediums. Further, the nitride semiconductor laser element, being capable of wavelength conversion of emitted light to a visible region, is expected also as a light source for visible light of illumination, backlight and the like. Then, with a view to expanding applications of the nitride semiconductor laser element, techniques for stabilizing its operations or enhancing its output power have been developed and discussed. When the nitride semiconductor laser element is enhanced to higher power, heat sink measures for efficiently dissipating heat generation of the nitride semiconductor laser element become important. For this purpose, junction down mounting that is advantageous in terms of heat sink has been under discussion as a mounting of nitride semiconductor laser elements.

Conventionally, there has been provided a nitride semiconductor laser element in which a nitride semiconductor is left exposed from one side face (see, e.g., JP 2007-180522 A (PTL 1)). In this nitride semiconductor laser element, a stripe-shaped ridge portion extending along a lengthwise direction of a resonator is formed in a nitride semiconductor laser element. Also, on a ridge portion-side surface of the nitride semiconductor laser element, a pair of crack preventing grooves are formed so as to sandwich the ridge portion. The nitride semiconductor is exposed from these crack preventing grooves.

In process of junction down mounting of such a nitride semiconductor laser element on a submount, solder between the nitride semiconductor laser element and the submount crawls up and sticks to side faces of the nitride semiconductor laser element. In this case, the solder intrudes into the crack preventing grooves.

As a result, in the nitride semiconductor laser element, there may arise a failure that p-type nitride semiconductor and n-type nitride semiconductor are short-circuited to each other via solder, leading to decreases in yield as a problem.

In addition, in comparison to the side face of AlGaAs semiconductor lasers, the side face of the nitride semiconductor laser element is formed into an outwardly projecting curved surface, which facilitates crawl-up of the solder.

### SUMMARY OF INVENTION

### Technical Problem

Accordingly, an object of the present invention is to provide a semiconductor laser device, as well as a manufacturing method therefor, capable of solving the problem of yield decreases in the structure for mounting a nitride semiconductor laser element onto the mount member.

### Solution to Problem

In order to achieve the above object, there is provided a semiconductor laser device comprising:

a mount member; and

a nitride semiconductor laser element which is mounted on a surface of the mount member with a conductive adhesive so that a nitride semiconductor is exposed from a side face thereof, wherein

the conductive adhesive is positioned between the mount member and the nitride semiconductor laser element and smaller in width than the nitride semiconductor laser element.

According to the semiconductor laser device constructed as described above, mounting of the nitride semiconductor laser element is done so that the width of the conductive adhesive becomes smaller than that of the nitride semiconductor laser element. As a result of this, the conductive adhesive can be prevented from crawling up onto the side face of the nitride semiconductor laser element.

Accordingly, short-circuits due to the sticking of the conductive adhesive on the side face of the nitride semiconductor laser element can be prevented, so that the issue of yield decreases can be solved.

Also, since the conductive adhesive can be prevented from sticking to the side face of the nitride semiconductor laser element, the device reliability can be enhanced.

Further, in a case where the conductive adhesive is solder as an example, although the solder is poor in thermal conductivity, yet the contact area between the solder and the submount is so narrow that heat sink of the submount member is not obstructed by the solder.

In one embodiment of the invention, a crack preventing groove is formed on a mount member-side surface of the nitride semiconductor laser element, and

the conductive adhesive is opposed to a region other than the crack preventing groove on the mount member-side surface of the nitride semiconductor laser element.

According to the semiconductor laser device of this embodiment, mounting of the nitride semiconductor laser element is done so that conductive adhesive is opposed to a region other than the crack preventing grooves on the mount member-side surface of the nitride semiconductor laser element. As a result of this, the conductive adhesive can be prevented from intruding into the crack preventing grooves.

Therefore, even though the nitride semiconductor is exposed from the crack preventing grooves, short-circuits due to intrusion of the conductive adhesive into the crack preventing grooves can be prevented;

In one embodiment of the invention, part of the side face of the nitride semiconductor laser element is covered with a dielectric.

According to the semiconductor laser device of this embodiment, since part of the side face of the nitride semiconductor laser element is covered with the dielectric, sticking of the conductive adhesive to part of the side face of the nitride semiconductor laser element can reliably be prevented.

In one embodiment of the invention, the crack preventing groove is covered with a dielectric.

According to the semiconductor laser device of this embodiment, even in a case where the side faces and bottom faces of the crack preventing grooves are made from nitride semiconductor, since the crack preventing grooves are covered with the dielectric, sticking of the conductive adhesive to the side faces and bottom faces of the crack preventing grooves can reliably be prevented.

In one embodiment of the invention, the dielectric contains at least one of zirconia, AlN, AlON, diamond, DLC and SiO₂.

According to the semiconductor laser device of this embodiment, since the dielectric contains at least one of zirconia, AlN, AlON, diamond, DLC and SiO₂, optical loss can be reduced.

In one embodiment of the invention, the nitride semiconductor laser element is placed on the mount member in such a manner that a light-emitting end face protrudes from a region on the mount member.

According to the semiconductor laser device of this embodiment, since the nitride semiconductor laser element is placed on the mount member in such a manner that the light-emitting end face of the nitride semiconductor laser element protrudes from a region on the mount member, turn off of emitted light emitted from the light-emitting end face as well as short-circuits due to crawl-up of the solder onto the light-emitting end face can be prevented.

In one embodiment of the invention, a distance between a plane containing the light-emitting end face of the nitride semiconductor laser element and a plane containing the end face of the mount member on the light-emitting end face-side is set to within a range from 100 nm to 100 μm.

According to the semiconductor laser device of this embodiment, since a distance between a plane containing the light-emitting end face of the nitride semiconductor laser element and a plane containing the end face of the mount member on the light-emitting end face-side is set to within a range from 100 nm to 100 μm, the COD (Catastrophic Optical Damage) level can be heightened and moreover the yield can also be enhanced.

With the distance less than 100 nm, the yield abruptly lowers, resulting in unsuccessful manufacturing efficiency. Also, with the distance over 100 μm, the COD level considerably lowers, resulting in lowered reliability.

IN one embodiment of the invention, the mount member is a submount whose principal material is AlN, diamond, SiC or Cu.

According to the semiconductor laser device of this embodiment, since the mount member is a submount whose principal material is AlN, diamond, SiC or Cu, a high thermal conductivity can be obtained, and moreover the reliability and thermal saturation level can be heightened.

In one embodiment of the invention, the conductive adhesive is Au—Sn solder, Sn—Ag—Cu solder or Ag solder.

According to the semiconductor laser device of this embodiment, since the conductive adhesive is Au—Sn solder, Sn—Ag—Cu solder or Ag solder. Therefore, a high thermal conductivity can be obtained, and moreover the reliability and thermal saturation level can be heightened.

In one embodiment of the invention, the mount member is a stem.

According to the semiconductor laser device of this embodiment, since the mount member is a stem, nonuse of a submount allows the thermal resistance to be lowered inexpensively, and increases in thermal resistance due to the conductive adhesive can be lowered.

In one embodiment of the invention, the nitride semiconductor laser element includes

a ridge portion, and

terrace portions formed on both sides of the ridge portion and generally equal in height to the ridge portion.

According to the semiconductor laser device of this embodiment, since terrace portions generally equal in height to the ridge portion are formed on both sides of the ridge portion, the ridge portion can be protected from mechanical shocks by the terrace portions.

In one embodiment of the invention, the nitride semiconductor laser element has an electrode electrically connected to the mount member via the conductive adhesive, and

the electrode has a thickness within a range from 1.5 μm to 1100 μm.

According to the semiconductor laser device of this embodiment, since the thickness of the electrode is within a range from 1.5 μm to 1100 μm, the forward voltage can be suppressed as a small one.

With the thickness of the electrode equal to 1.5 μm, the forward voltage can no longer be suppressed small. Also, with the thickness of the electrode over 1100 μm, there occurs peeling of the electrode.

In one embodiment of the invention, the electrode contains at least one of Au, Ag and Cu.

According to the semiconductor laser device of this embodiment, since the electrode contains at least one of Au, Ag and Cu, a high thermal conductivity can be obtained, and moreover the reliability and thermal saturation level can be heightened.

In one embodiment of the invention, a plurality of the nitride semiconductor laser elements are included in the semiconductor laser device.

According to the semiconductor laser device of this embodiment, since a plurality of the nitride semiconductor laser elements are included in the semiconductor laser device, a high optical-power device can be provided in one package.

Also, there is provided a method for manufacturing a semiconductor laser device comprising:

a formation step for forming a conductive adhesive on a surface of a mount member; and

a mounting step for placing a nitride semiconductor laser element on the conductive adhesive so that a nitride semiconductor is exposed from a side face of the nitride semiconductor laser element, whereby the nitride semiconductor laser element is mounted on the surface of the mount member, wherein

a width to which the conductive adhesive is formed in the formation step is a width which is so predetermined that a width of the conductive adhesive after the mounting step becomes smaller than a width of the nitride semiconductor laser element.

According to the semiconductor laser device manufacturing method constituted as described above, since the width to which the conductive adhesive is formed in the formation step is a width which is so predetermined that the width of the conductive adhesive after the mounting step becomes smaller than the width of the nitride semiconductor laser element. Therefore, it becomes possible to prevent the conductive adhesive from crawling up onto the side faces of the nitride semiconductor laser element even though the nitride semiconductor laser element is placed on the conductive adhesive.

Accordingly, short-circuits due to the sticking of the conductive adhesive on the side faces of the nitride semiconductor laser element can be prevented, so that the issue of yield decreases can be solved.

Also, since the sticking of the conductive adhesive onto the side faces of the nitride semiconductor laser element can be prevented, device reliability can be enhanced.

Further, in a case where the conductive adhesive is solder as an example, although the solder is poor in thermal conductivity, yet the contact area between the solder and the submount is so narrow that heat sink of the submount member is not obstructed by the solder.

In one embodiment of the invention, the nitride semiconductor laser element has an electrode electrically connected to the mount member via the conductive adhesive, and

the width of the conductive adhesive in the formation step is 50% or more of a width of the electrode and smaller than the width of the nitride semiconductor laser element at least by an extent corresponding to a thickness of the conductive adhesive.

According to the semiconductor laser device manufacturing method of this embodiment, the width of the conductive adhesive in the formation step is 50% or more of the width of the electrode and smaller than the width of the nitride semiconductor laser element at least by an extent corresponding to the thickness of the conductive adhesive. As a result of this, the width of the conductive adhesive after the mounting step can reliably be made smaller than the width of the nitride semiconductor laser element.

If the width of the conductive adhesive in the formation step is 50% or less of the width of the electrode, then the nitride semiconductor laser element cannot be firmly fixed to the mount member, so that the nitride semiconductor laser element may be released off from the mount member.

Unless the width of the conductive adhesive in the formation step is set smaller than the width of the nitride semiconductor laser element by an extent corresponding to the thickness of the conductive adhesive, there occurs crawl-up of the conductive adhesive onto the side faces of the nitride semiconductor laser element.

### ADVANTAGEOUS EFFECTS OF INVENTION

According to the semiconductor laser device of the present invention, since the mounting of the nitride semiconductor laser element is performed so that the width of the conductive adhesive becomes smaller than that of the nitride semiconductor laser element, crawl-up of the conductive adhesive onto the side faces of the nitride semiconductor laser element can be prevented.

Accordingly, short-circuits due to the sticking of the conductive adhesive on the side faces of the nitride semiconductor laser element can be prevented, so that the issue of decreases in manufacturing yield can be solved.

Also, since the sticking of the conductive adhesive onto the side faces of the nitride semiconductor laser element can be eliminated, device reliability can be enhanced.

According to the semiconductor laser device manufacturing method of the present invention, the width to which the conductive adhesive is formed in the formation step is so predetermined that the width of the conductive adhesive after the mounting step becomes smaller than the width of the nitride semiconductor laser element. Therefore, it becomes possible to prevent the conductive adhesive from crawling up onto the side faces of the nitride semiconductor laser element even though the nitride semiconductor laser element is placed on the conductive adhesive.

Accordingly, short-circuits due to the sticking of the conductive adhesive on the side faces of the nitride semiconductor laser element can be prevented, so that the issue of decreases in manufacturing yield can be solved.

Also, since the sticking of the conductive adhesive onto the side faces of the nitride semiconductor laser element can be eliminated, device reliability can be enhanced.

### BRIEF DESCRIPTION OF DRAWINGS

The present invention will become more fully understood from the detailed description given hereinbelow and the accompanying drawings which are given by way of illustration only, and thus are not intended to limit the present invention, and wherein:

FIG. 1 is a schematic sectional view of a nitride semiconductor laser element according to a first embodiment of the present invention;

FIG. 2 is a schematic front view of a nitride semiconductor laser device of the first embodiment;

FIG. 3 is a view including a schematic front view, a schematic top view and a schematic side view of the nitride semiconductor laser device of the first embodiment;

FIG. 4 is a graph showing a relationship between protrusion amount of a light-emitting end face and COD level of the nitride semiconductor laser element;

FIG. 5 is a graph showing a relationship between protrusion amount of the light-emitting end face and yield;

FIG. 6 is a graph showing a relationship between forward voltage and thickness of a p-side electrode of the nitride semiconductor laser element of the first embodiment;

FIG. 7 is a schematic front view of a nitride semiconductor laser device provided by a prior-art mounting method;

FIG. 8 is a schematic sectional view of a nitride semiconductor laser element according to a sixth comparative example of the present invention;

FIG. 9 is a schematic sectional view of a nitride semiconductor laser element according to a second embodiment of the present invention;

FIG. 10A is a schematic sectional view for explaining one manufacturing step of the nitride semiconductor laser device according to the second embodiment;

FIG. 10B is a schematic sectional view for explaining one manufacturing step of the nitride semiconductor laser device according to the second embodiment;

FIG. 11 is a schematic front view of a nitride semiconductor laser device of a third embodiment;

FIG. 12 is a schematic front view of a nitride semiconductor laser device of a fourth embodiment;

FIG. 13 is a schematic sectional view of a modification of the nitride semiconductor laser device according to the fourth embodiment of the invention; and

FIG. 14 is a schematic perspective view of a main part of a nitride semiconductor laser device according to a fifth embodiment of the invention.

### DESCRIPTION OF EMBODIMENTS

For description of various embodiments of the present invention hereinbelow, meanings of the following terms are clarified in advance.

First, the term, “crack preventing groove,” refers to a groove formed in a substrate contained in a nitride semiconductor laser element or a groove formed in a nitride semiconductor layer contained in a nitride semiconductor laser element, the groove being a stripe-shaped recess portion for relaxing stress that the nitride semiconductor layer undergoes.

The term, “nitride semiconductor laser element,” refers to a chip resulting from deposition of a nitride semiconductor grown layer on a process substrate and thereafter various types of processes to form an electrode layer, and dividing the substrate into individual chips.

The term, “nitride semiconductor laser device,” refers to a device in which, given a ridge portion is provided in a nitride semiconductor laser element, the nitride semiconductor laser element is mounted on a stem or submount or other mount member by a junction down method.

The term, “mount member,” refers to a stem on which a nitride semiconductor laser element is mounted, or a submount mounted on the stem. Therefore, for example, a description, “mounting a nitride semiconductor laser element on a mount member by a junction down method,” refers to mounting a nitride semiconductor laser element directly on the stem by the junction down mounting, or mounting a nitride semiconductor laser element onto a submount mounted on the stem by the junction down method.

The term, “conductive adhesive,” refers to a high-temperature baking type metal adhesive typified by alloys such as solder having metal bonds between metal surfaces at two or more points for electrical connection or physical connection or by Ag paste, as well as to metal adhesives made by mixing of polymer and conductive substances.

### First Embodiment

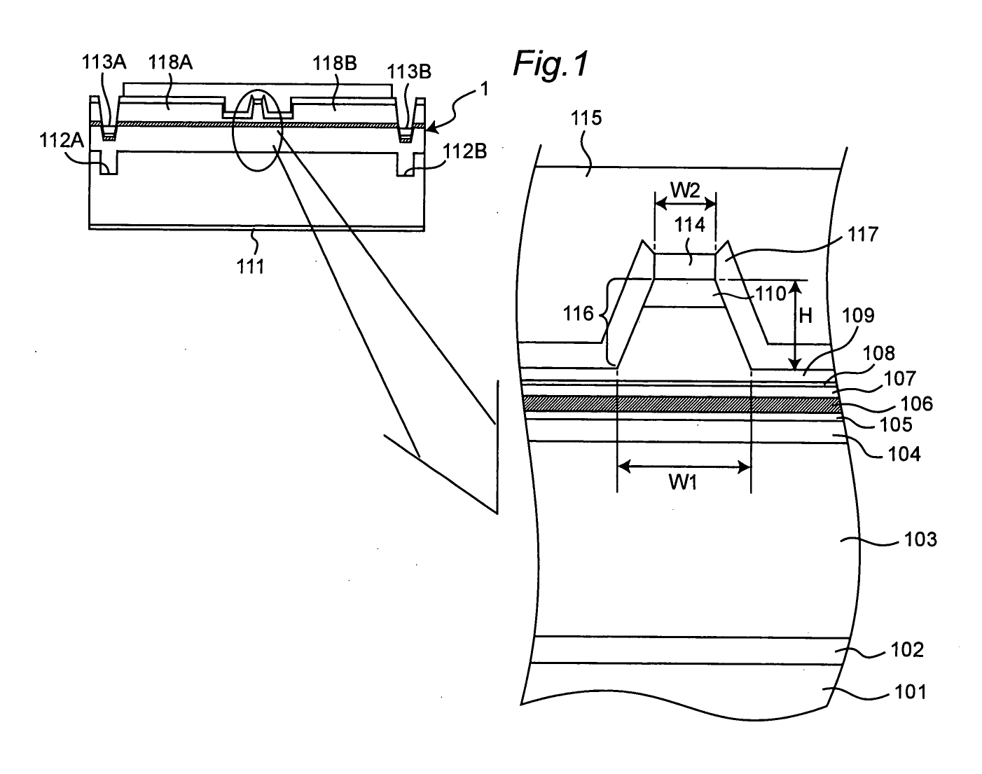

FIG. 1 is a schematic sectional view of a nitride semiconductor laser element 1 according to a first embodiment of the invention.

The nitride semiconductor laser embodiment 1 includes an n-type (hereinafter, n conductive type will be referred to as “n-” and p conductive type as “p-”) GaN substrate 101. The nitride semiconductor laser element further includes, as layers formed on the n-GaN substrate 101 on one another, a 0.5 μm thick n-GaN layer 102, a 2 μm thick n-Al_{0.05}Ga_{0.95}N lower clad layer 103, a 0.1 μm thick n-GaN guide layer 104, a 20 nm thick GaN lower adjoining layer 105, an active layer 106, a 50 nm thick GaN upper adjoining layer 107, a 20 nm thick p-Al_{0.2}Ga_{0.8}N carrier barrier layer 108, a 0.6 μm thick p-Al_{0.1}Ga_{0.9}N upper clad layer 109, and a 0.1 μm p-GaN contact layer 110. Then, nitride semiconductors are exposed from a side face of the nitride semiconductor laser element 1. Further, crack preventing grooves 113A, 113B are formed on an upper surface (a surface opposite to the substrate 101 side) of the nitride semiconductor laser element 1.

Crack preventing grooves 112A, 112B are formed on a surface of the substrate 101. The nitride semiconductor is exposed from these crack preventing grooves 112A, 112B. An n-side electrode 111 is formed on a back surface of the substrate 101. This n-side electrode 111 has a structure of Ti/Al/Mo/Pt/Au as viewed from the substrate 101 side.

On the contact layer 110 is formed a p-side contact electrode 114. Further, on the p-side contact electrode 114 is formed a p-side electrode 115. This p-side electrode 115 has a structure of Mo/Au/Au as viewed from the p-side contact electrode 114 side.

A striped-shaped ridge portion 116 is formed in the upper clad layer 109 and the contact layer 110. This ridge portion 116 extends in a light-emitting direction (<1-100> direction) to form a ridge stripe type waveguide. The ridge portion 116 has a lower end width W1 of about 7 μm, an upper end width W2 of 7.2 μm, and a height H of 0.1 μm.

Both side faces of the ridge portion 116 are covered with a 500 nm thick SiO₂ dielectric film 117. This dielectric film 117 does not cover an upper surface of the ridge portion 116, i.e., the surface of the contact layer 110. Portions of the dielectric film 117 with which both side faces of the ridge portion 116 are covered are protruded from both sides of the ridge portion 116 in a direction counter to the substrate 101. This structure is formed by forming a SiO₂ dielectric film on the upper surface and both side faces of the ridge portion 116 and thereafter removing only portions of the dielectric film that cover the upper surface of the ridge portion 116. Therefore, the protrusion amount of the dielectric film 117 from the upper surface of the ridge portion 116 becomes equal to the film thickness of the dielectric film 117. By such a dielectric film 117, light confinement and current constriction effects are obtained while improvement of heat radiation is fulfilled.

In the upper clad layer 109, terrace portions 118A, 118B are formed so as to sandwich the ridge portion 116. These terrace portions 118A, 118B are generally equal in height to the ridge portion 116. The upper surface and side faces of the terrace portions 118A, 118B are covered with the dielectric film 117. Then, a surface of the dielectric film 117 on the terrace portions 118A, 118B is positioned higher than the upper surface of the ridge portion 116. In other words, a height from the surface of the substrate 101 to the surface of the dielectric film 117 on the terrace portions 118A, 118B is larger than the height from the surface of the substrate 101 to the upper surface of the ridge portion 116.

The carrier barrier layer 108, the upper clad layer 109 and the contact layer 110 are each doped with Mg (magnesium) as a p-dopant at a concentration of 1×10¹⁹ cm⁻³-1×10²⁰ cm⁻³. A typical example of the doping concentration for the upper clad layer 109 and the contact layer 110 is 4×10¹⁹ cm⁻³. In addition, in this embodiment, it is also possible to exclude the contact layer 110 while the upper clad layer 109 also plays the role of the contact layer 110.

The active layer 106 has a multiple quantum well structure (well number 3) that an undoped In_{0.15}Ga_{0.85}N well layer (thickness 4 nm) and an undoped GaN barrier layer (thickness 8 nm) are formed in an order of well layer, barrier layer, well layer, barrier layer and well layer. The well layer and the barrier layer may be formed by InₓGaₗ₋ₓN (0≦x<1), AlₓGa₁₋ₓN (0≦x<1), InGaAlN, GaN₁₋ₓAsₓ (0<x<1), GaN₁₋ₓPₓ (0<x<1) or nitride semiconductors of these compounds, where the composition is such that the barrier layer is larger in band gap energy than the well layer. Also, with a view to lowering the oscillation threshold of the element, the active layer is preferably provided in a multiple quantum well structure (MQW structure) having a well number of 2 to 4. However, the active layer may also be provided in an SQW (single quantum well) structure, in which case the barrier layer, as herein referred to, to be sandwiched by well layers is not present.

The individual nitride semiconductor layers of the nitride semiconductor laser element 1 constructed as described above can be stacked by known crystal growth process for nitride semiconductor, e.g., MOCVD (Metal Organic Chemical Vapor Deposition) process.

The n-side electrode 111 is formed by EB (electron beam) vapor deposition process. Also, the p-side contact electrode 114 is formed to a thickness of 50 nm by EB vapor deposition process. Then, for the p-side electrode 115, after 15 nm thick Mo and 25 nm thick Au are formed successively by sputtering process, the Au film is formed finally to a thickness of 3 μm by electroless plating process. The dielectric film 117 is formed by plasma CVD process.

A laser wafer obtained in the way shown above is bar divided by scribing and cleaving at 800 μm intervals, where AR (Anti-Reflection) coat film made of AlON/Al₂O₃ is formed in front of the bar and an HR (High-Reflection) coat film made of AlON and five pairs of SiO₂/TiO₂ is formed in rear of the bar by ECR (Electron Cyclotron Resonance) sputtering process. The AR coat film has a reflectivity of 10%, and the HR coat film has a reflectivity of 95%. After formation of such AR coat film and HR coat film, the bar wafer is chip divided, by which the nitride semiconductor laser element 1 is obtained.

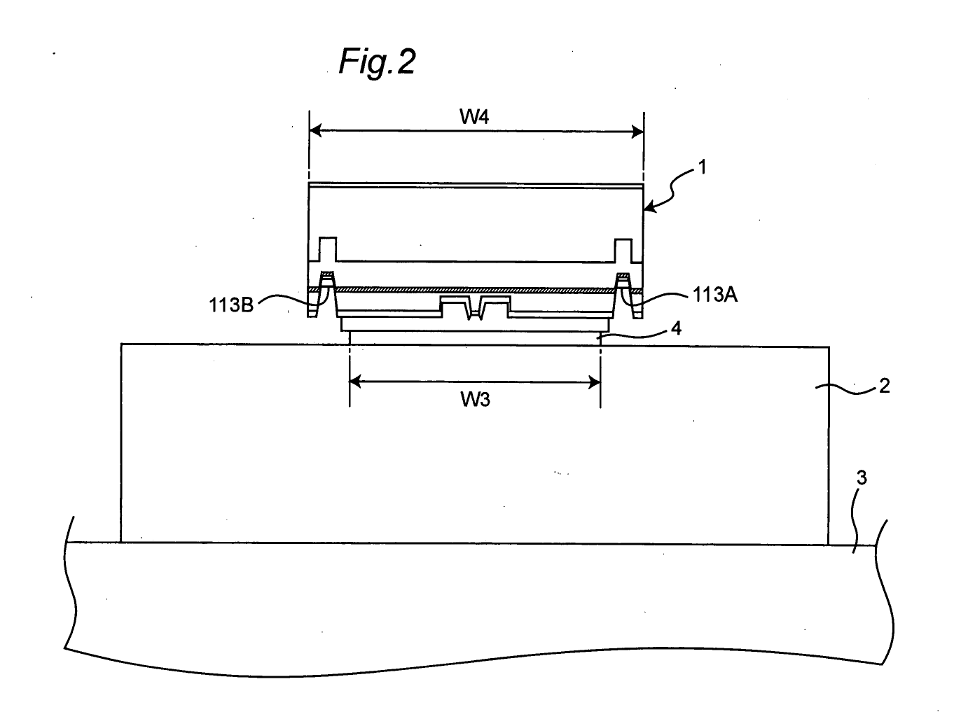

FIG. 2 is a schematic front view of a nitride semiconductor laser device including the above-described nitride semiconductor laser element 1.

The nitride semiconductor laser device includes a submount 2 made of AlN, and a stem 3 mounted via the submount 2 and formed of a Cu block stem having diameter of 9 mm. It is noted that the submount 2 is an example of the mount member.

On a surface of the submount 2, the nitride semiconductor laser element 1 is mounted by the junction down mounting. A Au—Sn solder 4 is used for this mounting. More specifically, the solder 4 is present between the nitride semiconductor laser element 1 and the submount 2 so as to make the nitride semiconductor laser element 1 bonded to the submount 2. Then, a width W3 of the solder 4 is smaller than a lateral width W4 of the nitride semiconductor laser element 1. The solder 4 is opposed to a region between the crack preventing groove 113A and the crack preventing groove 113B. That is, the solder 4 is not opposed to the crack preventing grooves 113A, 113B. In other words, the solder 4 is absent under the crack preventing grooves 113A, 113B. It is noted here that the lateral width W4 of the nitride semiconductor laser element refers to a width vertical to the light-emitting direction and parallel to the surface of the substrate 101. It is noted that the solder 4 is an example of the conductive adhesive.

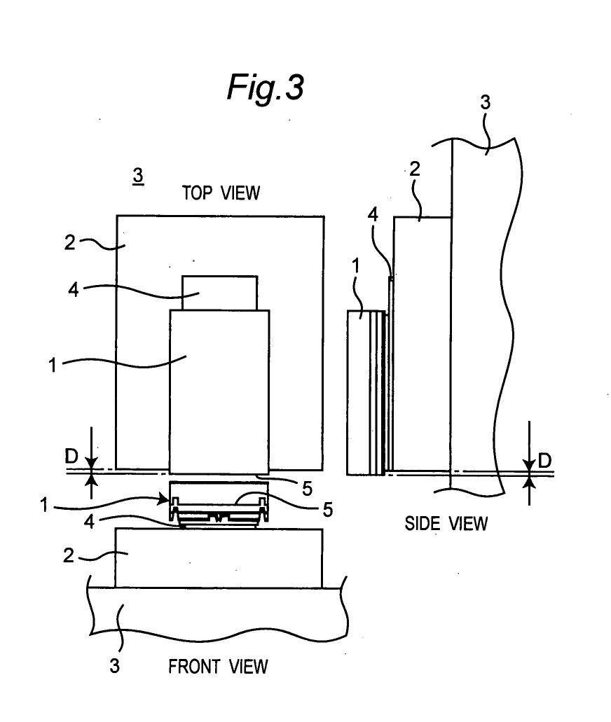

FIG. 3 is a view including a schematic front view, a schematic top view and a schematic side view of the above-described nitride semiconductor laser device.

The nitride semiconductor laser element 1 is so mounted that a light-emitting end face 5 of the nitride semiconductor laser element 1 is protruded from the region on the submount 2. A distance D between a plane containing the light-emitting end face 5 and a plane containing the end face of the submount 2 on the light-emitting end face 5 side is set to within a range from 100 nm to 100 μm.

If the distance D is less than 100 nm, the solder may crawl up onto the light-emitting surface 5 at a higher probability, resulting in a lowered yield.

If the distance D is over 100 μm, then the COD (Catastrophic Optical Damage) level abruptly lowers. With the distance D over 100 μm, when the temperature of the light-emitting end face 5 was measured by thermography, the temperature became 100° C. or more higher than in a case with a distance D of 3 μm. From this fact, it can be understood that with the distance D over 100 μm, generated heat of the light-emitting end face 5 cannot be radiated.

Given that the light-emitting end face 5 is placed within the region on the submount 2, i.e., that the light-emitting end face 5 is withdrawn from one end face of the submount 2 on the light-emitting end face 5 side, emitted light of the nitride semiconductor laser element 1 is turned off by the submount 2, undesirably.

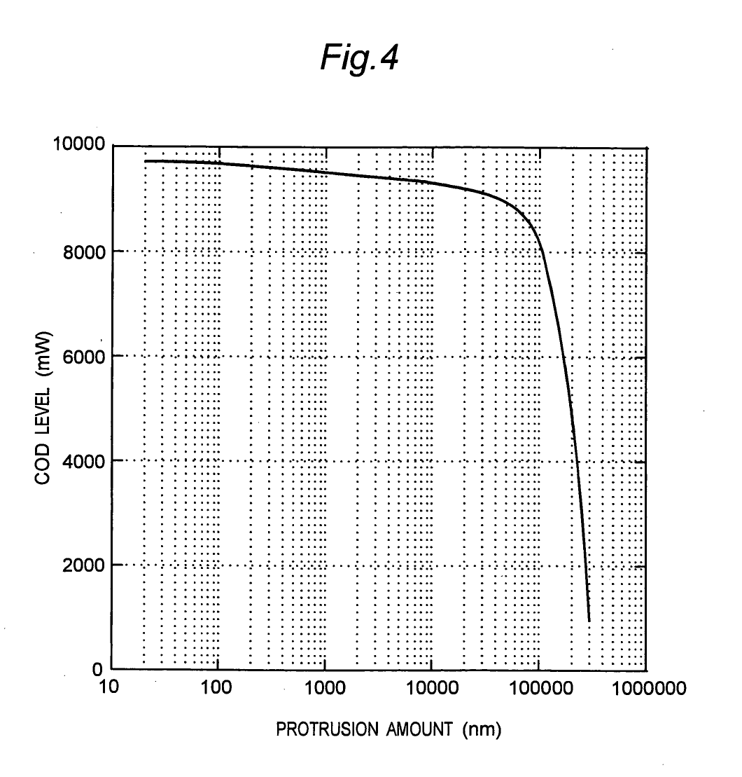

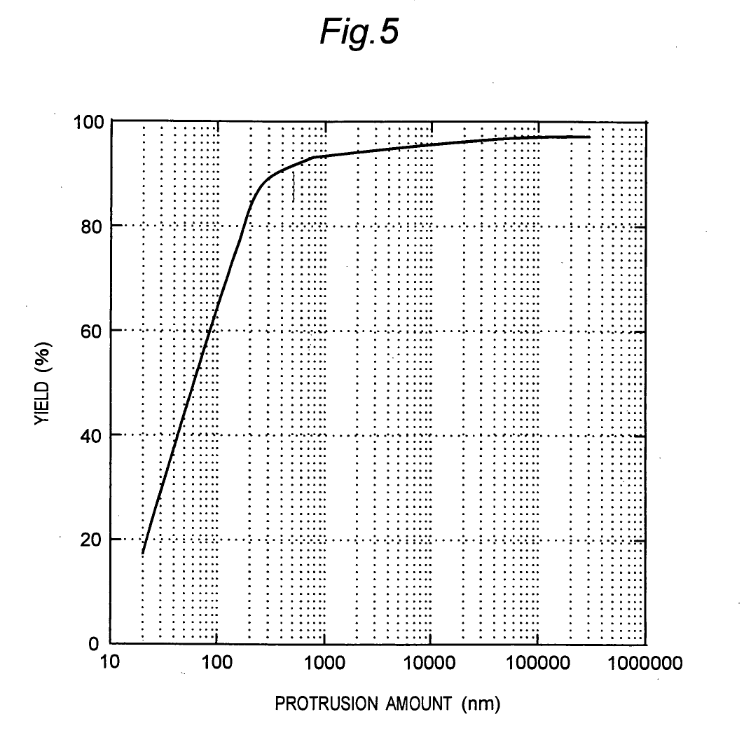

FIG. 4 is a graph showing a relationship between protrusion amount of the light-emitting end face 5 and COD level of the nitride semiconductor laser element 1. FIG. 5 is a graph showing a relationship between protrusion amount of the light-emitting end face 5 and yield. The protrusion amount in FIGS. 4 and 5 corresponds to the distance D.

As apparent from FIGS. 4 and 5, when the protrusion amount of the light-emitting end face 5 is within a range from 100 nm to 100 μm, then the COD level can be made higher and moreover the yield can also be made higher.

The p-side electrode 115 electrically connected to the submount 2 via the solder 4 is set to a thickness within a range from 1.5 μm to 1100 μm.

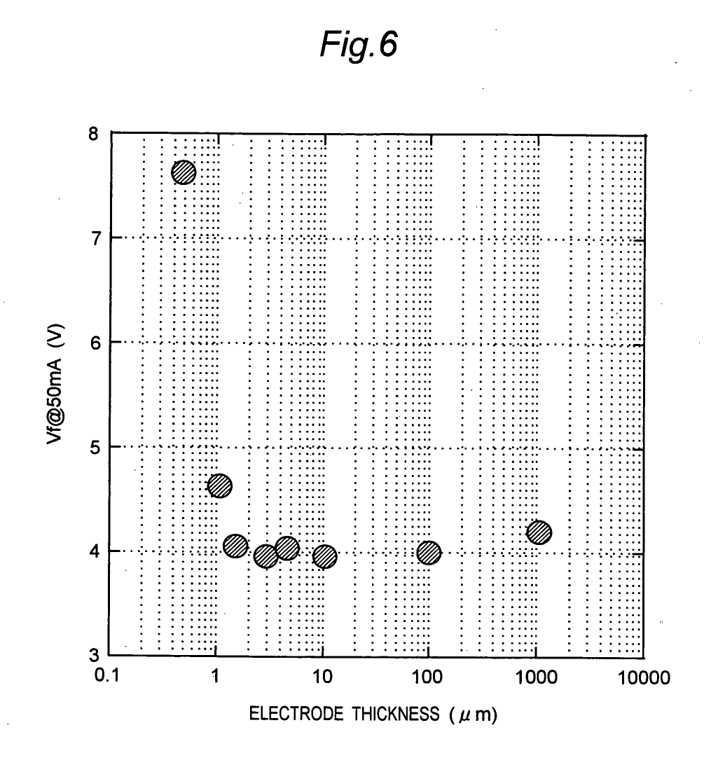

FIG. 6 is a graph showing a relationship between forward voltage of the nitride semiconductor laser element 1 and thickness of the p-side electrode 115. In FIG. 6, the thickness of the p-side electrode 115 is described as “electrode thickness.”

As seen from FIG. 6, when the thickness of the p-side electrode 115 is within a range from 1.5 μm to 1100 μm, then the forward voltage can be suppressed small.

Now, the mounting of the nitride semiconductor laser device will be described below.

First, on a surface of an AlN member for forming the submount 2, a AuSn layer as an example of the conductive adhesive is formed by sputtering process, and thereafter the AuSn layer is patterned by photolithography. In this case, the width of the AuSn layer is set to 50% or more of the width of the p-side electrode 115 and moreover smaller than the lateral width W4 of the nitride semiconductor laser element 1 at least by an extent corresponding to the thickness of the AuSn layer. Thereafter, the AlN member is divided by dicing, by which the submount 2 is prepared.

Next, the nitride semiconductor laser element 1 is placed on the AuSn layer and heated to make the AuSn layer and the p-side electrode 115 of Au alloyed together, thereafter being cooled and solidified. As a result of this, the nitride semiconductor laser element 1 is fixed to the surface of the submount 2 via the solder 4. In this process, the width W3 of the solder 4 becomes smaller than the lateral width W4 of the nitride semiconductor laser element 1.

By the setting that the width of the AuSn layer is 50% or more of the width of the p-side electrode 115 and moreover smaller than the lateral width W4 of the nitride semiconductor laser element 1 at least by an extent corresponding to the thickness of the AuSn layer as shown above, it becomes possible to prevent AuSn from crawling up onto the side faces of the nitride semiconductor laser element 1 even though the nitride semiconductor laser element 1 is placed on the AuSn layer.

Accordingly, short-circuits due to the sticking of AuSn on the side faces of the nitride semiconductor laser element 1 can be prevented, so that the issue of yield decreases can be solved.

Also, since the sticking of AuSn onto the side faces of the nitride semiconductor laser element 1 can be prevented, device reliability can be enhanced.

Also, by the setting that the width of the AuSn layer is 50% or more of the width of the p-side electrode 115 and moreover smaller than the lateral width W4 of the nitride semiconductor laser element 1 at least by an extent corresponding to the thickness of the AuSn layer as shown above, the width W3 of the hardened solder 4 becomes smaller than the distance between the crack preventing groove 113A and the crack preventing groove 113B, preferably.

In addition, in the nitride semiconductor laser element 1, since the HR coat is formed from AlON/(SiO₂/TiO₂), which is a dielectric, there occur no short-circuits.

The above-described nitride semiconductor laser device, when thrown into room-temperature CW (Continuous Wave) operation, showed such successful characteristics as a threshold value of 100 mA and a slope efficiency of 1.8 W/A. Under drive conditions of 50° C., a pulse width of 1 μsec and a duty ratio of 50, the nitride semiconductor laser device yielded no thermal saturation until 3 W was reached. As a result of performing a reliability test under drive conditions of 50° C., a pulse width of 1 μsec, a duty ratio of 50% and an initial 2.6 W equivalent ACC (Automatic Current Control), the time when the optical output reaches 1.3 W, which is 50% of the initial value was estimated to be 20,000 hours.

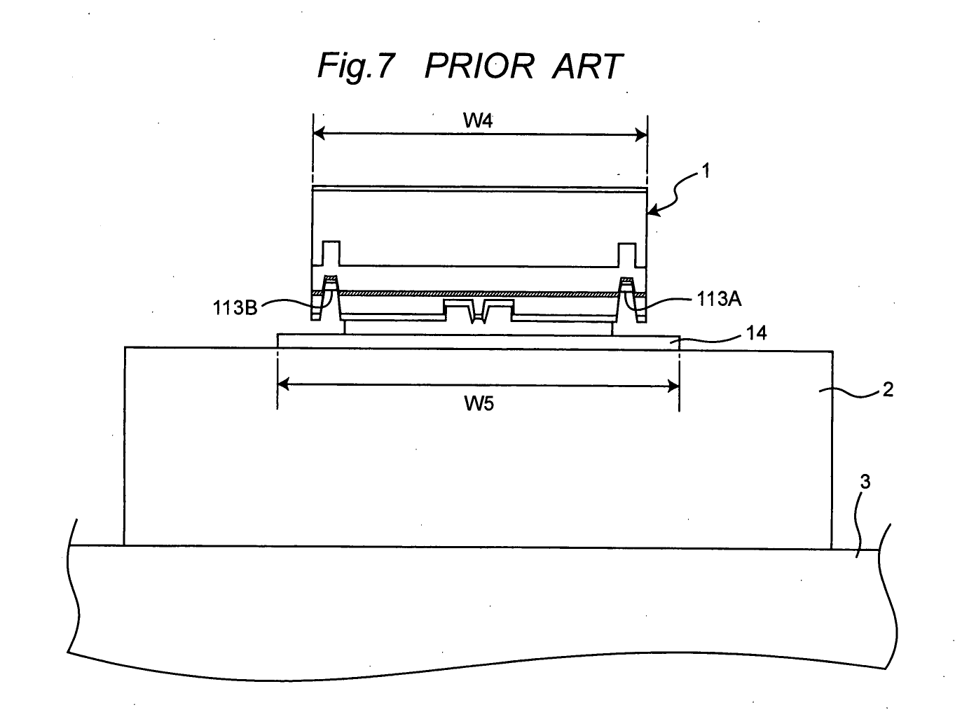

When the mounting of the nitride semiconductor laser device is done by a conventional method, a width W5 of a solidified solder 14 becomes larger than the lateral width W4 of the nitride semiconductor laser element 1 as shown in FIG. 7. Therefore, the solder 14 is present under the side faces of the nitride semiconductor laser element 1 as well as under the crack preventing grooves 113A, 113B. With such a conventional method, the solder 14 would crawl up into the crack preventing grooves 113A, 113B or onto the side faces of the nitride semiconductor laser element 1. Then, there would occur failures due to p-n short-circuits within the crack preventing grooves 113A, 113B or at the side faces of the nitride semiconductor laser element 1, resulting in large yield decreases.

Although the submount 2 made of AlN is used in this first embodiment, it is also allowable to use a submount 2 whose primary material is diamond, SiC or Cu.

Although the Au—Sn solder 4 is used in the first embodiment, yet it is allowable to use Sn—Ag—Cu solder, Ag solder, high-temperature baking type Ag paste or conductive resin or the like. Here, Ag solder means an adhesive containing Ag such as Ag paste or the like.

Although the p-side electrode 115 containing Au is used in the first embodiment, yet it is also allowable to use a p-side electrode containing at least one of Au, Ag and Cu.

Although the dielectric film 117 made of SiO₂ is used in the first embodiment, yet it is also allowable to use a dielectric film made of at least one of AlN, AlON, diamond and DLC (Diamond-like Carbon).

For example, a nitride semiconductor laser device is fabricated in the same manner as in the first embodiment except that a dielectric film made of AlON is used instead of the dielectric film 117. This nitride semiconductor laser device shows a thermal saturation level of 2.8 W under drive conditions of 50° C., a pulse width of 1 μsec and a duty ratio of 50%, having performance comparable to the first embodiment.

Also, a nitride semiconductor laser device is fabricated in the same manner as in the first embodiment except that a dielectric film made of AlN or DLC is used instead of the dielectric film 117. This nitride semiconductor laser device also has performance comparable to the first embodiment.

Also, a nitride semiconductor laser device is fabricated in the same manner as in the first embodiment except that a dielectric film made of zirconia is used instead of the dielectric film 117. This nitride semiconductor laser device showed a thermal saturation level of 2.4 W. Therefore, the nitride semiconductor laser device proved to be usable if its applications are limited. Besides, the nitride semiconductor laser device had no difference in yield and reliability from the first embodiment.

In contrast to these, a nitride semiconductor laser device is fabricated in the same manner as in the first embodiment except that a dielectric film made of polyimide is used instead of the dielectric film 117. This nitride semiconductor laser device has a thermal saturation level as low as 0.7 W, proving to be unusable, with a reliability test result that devices came to a sudden death in about 200 hours one after another.

Hereinbelow, Comparative Example 1-12 of the first embodiment will be described. It is noted here that Comparative Examples 1, 3, 5, 8, 9, 11, 12 are modifications of the first embodiment, i.e., each one embodiment of the present invention as well.

### (I) Comparative Example 1

A nitride semiconductor laser device was fabricated in the same manner as in the first embodiment except that the Au—Sn solder 4 used for bonding of the nitride semiconductor laser element 1 and the submount 2 to each other was replaced with Sn/Ag/Cu. This nitride semiconductor laser device, when thrown into room-temperature CW (Continuous Wave) operation, showed such successful characteristics as a threshold value of 100 mA and a slope efficiency of 1.8 W/A. Under drive conditions of 50° C., a pulse width of 1 μsec and a duty ratio of 50%, the nitride semiconductor laser device yielded no thermal saturation until 3 W was reached, showing no difference in yield and reliability from the first embodiment.

### (II) Comparative Example 2

A nitride semiconductor laser device was fabricated in the same manner as in the first embodiment except that the Au—Sn solder 4 used for bonding of the nitride semiconductor laser element 1 and the submount 2 to each other was replaced with Ag paste. Under drive conditions of 50° C., a pulse width of 1 μsec and a duty ratio of 50%, this nitride semiconductor laser device yielded thermal saturation at 1 W, being practically unusable.

### (III) Comparative Example 3

A nitride semiconductor laser device was fabricated in the same manner as in the first embodiment except that the submount 2 was replaced with a submount made of diamond. Under drive conditions of 50° C., a pulse width of 1 μsec and a duty ratio of 50%, the nitride semiconductor laser device yielded thermal saturation at 4 W. The nitride semiconductor laser device shows quite successful characteristics, but costs high.

Also, a nitride semiconductor laser device was fabricated in the same manner as in the first embodiment except that the submount 2 was replaced with a submount made of SiC or Cu. In either case, this nitride semiconductor laser device showed a thermal saturation level of 3 W. Whereas the nitride semiconductor laser device shows a lower thermal saturation level than the case using the submount made of diamond, but roughly equivalent in thermal saturation level to the case using the submount made of AlN, thus practically usable enough. Besides, the nitride semiconductor laser device had no difference in yield and reliability from the first embodiment.

### (IV) Comparative Example 4

A nitride semiconductor laser device was fabricated in the same manner as in the first embodiment except that the submount 2 was replaced with a submount made of Fe. Under drive conditions of 50° C., a pulse width of 1 μsec and a duty ratio of 50%, the nitride semiconductor laser device yielded thermal saturation at 0.7 W, practically unusable.

### (V) Comparative Example 5

A nitride semiconductor laser device was fabricated in the same manner as in the first embodiment except that the nitride semiconductor laser element 1 was mounted directly on a Cu block stem without intervening the submount 2. Under drive conditions of 50° C., a pulse width of 1 μsec and a duty ratio of 50%, the nitride semiconductor laser device showed a thermal saturation level of 4 W, excellently. Also, the nitride semiconductor laser device has no difference in yield and reliability from the first embodiment. However, since the Cu block stem is so designed as to allow the nitride semiconductor laser element 1 to be directly mounted, the nitride semiconductor laser device costs high.

### (VI) Comparative Example 6

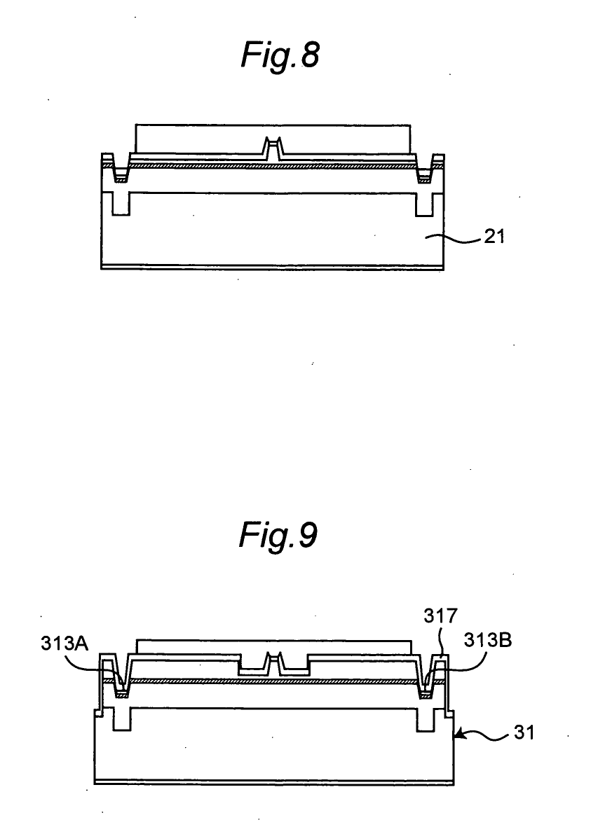

A nitride semiconductor laser element 21 shown in FIG. 8 is an element which was fabricated in the same manner as in the first embodiment except that the terrace portions 118A, 118B were excluded from the nitride semiconductor laser element 1. This nitride semiconductor laser element 21, when mounted on the submount 2 in the foregoing embodiment, incurs no p-n short-circuits but involves high voltage, practically unusable.

### (VII) Comparative Example 7

A nitride semiconductor laser device was fabricated in the same manner as in the first embodiment except that the thickness of Au contained in the p-side electrode 115 was set to 1.0 μm. This nitride semiconductor laser device incurs no p-n short-circuits but involves high voltage, practically unusable.

### (VIII) Comparative Example 8

A nitride semiconductor laser device was fabricated in the same manner as in the first embodiment except that the thickness of Au contained in the p-side electrode 115 was set to 1.5 μm. This nitride semiconductor laser device was comparable in characteristics to the first embodiment.

### (IX) Comparative Example 9

A nitride semiconductor laser device was fabricated in the same manner as in the first embodiment except that the thickness of Au contained in the p-side electrode 115 was set to 1100 μm. This nitride semiconductor laser device yielded a trouble that the Au was peeled off from the nitride semiconductor laser element 1, practically unusable. It is noted that the nitride semiconductor laser device was similar in characteristics to the first embodiment until the thickness of the Au reached 1000

### (X) Comparative Example 10

A nitride semiconductor laser device was fabricated in the same manner as in the first embodiment except that Au contained in the p-side electrode 115 was replaced with Al with the aim of cost reduction. This nitride semiconductor laser device rapidly deteriorated in about 1000 hours in a reliability test.

### (XI) Comparative Example 11

A nitride semiconductor laser device was fabricated in the same manner as in the first embodiment except that Au contained in the p-side electrode 115 was replaced with Cu with the aim of cost reduction. This nitride semiconductor laser device was similar in characteristics to the first embodiment, but showed poor mount yield so as not to lead to a cost reduction.

### (XII) Comparative Example 12

A nitride semiconductor laser device was fabricated in the same manner as in the first embodiment except that Au contained in the p-side electrode 115 was replaced with Ag with the aim of characteristic improvement. This nitride semiconductor laser device was similar in characteristics to the first embodiment, but showed a half-life of about 15000 hours in a reliability test.

### Second Embodiment

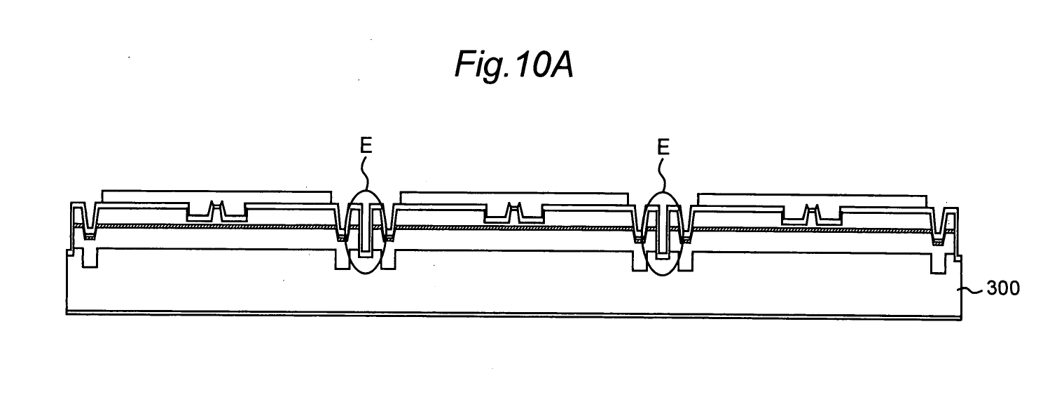

FIG. 9 is a schematic sectional view of a nitride semiconductor laser element 31 according to a second embodiment of the invention.

This nitride semiconductor laser element 31 includes a dielectric film 317, and the dielectric film 317 covers part of side faces of the nitride semiconductor laser element 31 as well as crack preventing grooves 313A, 313B. It is noted that the dielectric film 317 is an example of the dielectric.

In fabrication of the nitride semiconductor laser element 31, first as in the first embodiment, on an n-GaN substrate are layer-stacked an n-GaN layer, an n-Al_{0.1}Ga_{0.9}N lower clad layer, an n-GaN guide layer, a GaN lower adjoining layer, an active layer, a GaN upper adjoining layer, a p-Al_{0.2}Ga_{0.8}N carrier barrier layer, a p-Al_{0.1}Ga_{0.9}N upper clad layer, and a p-GaN contact layer layer-stacked one after another, and thereafter ridge portions and terrace portions are formed.

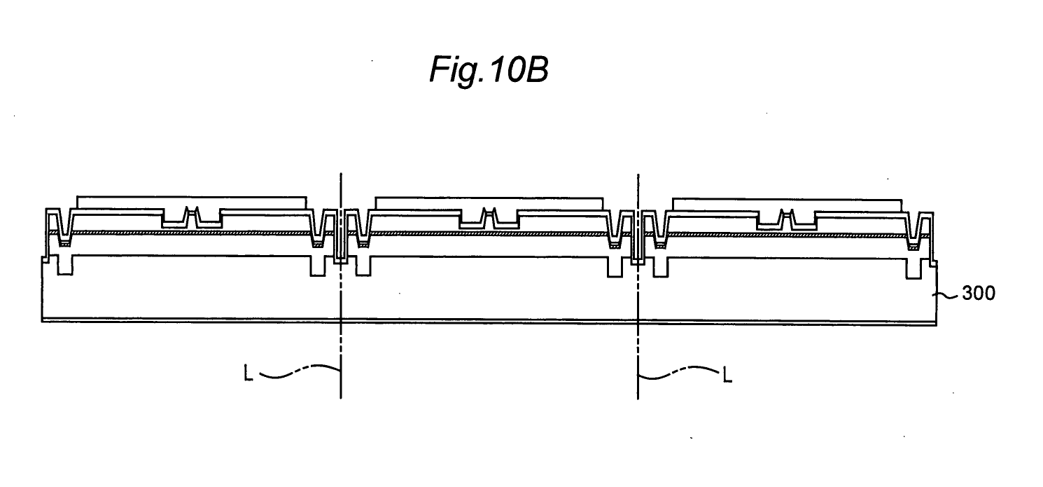

Next, 5 μm deep grooves are formed at chip dividing portion surrounded by ellipses E in FIG. 10A, and thereafter a material layer of the dielectric film 317 is stacked all over.

Next, part of the material layer of the dielectric film 317 is etched so as to make upper surfaces of the ridge portions exposed, and thereafter p-side electrodes are formed on the ridge portions, by which a wafer 300 is obtained.

Finally, the wafer is chip divided along dividing lines L in FIG. 10B, by which a nitride semiconductor laser element 31 is obtained in plurality.

The nitride semiconductor laser element 31 fabricated in this way is mounted on the submount 2 as in the first embodiment. In this case, it is possible to securely prevent the solder 4 from sticking to the nitride semiconductor on bottom faces and side faces of the crack preventing grooves 313A, 313B as well as the nitride semiconductor at part of the side faces of the nitride semiconductor laser element 31.

In addition, when a distance to which the solder crawls up onto the side faces of the nitride semiconductor laser element 31 is not more than 5 μm, then there occur no short-circuits.

The dielectric film 317 contains at least one of zirconia, AlN, AlON, diamond, DLC and SiO₂.

### Third Embodiment

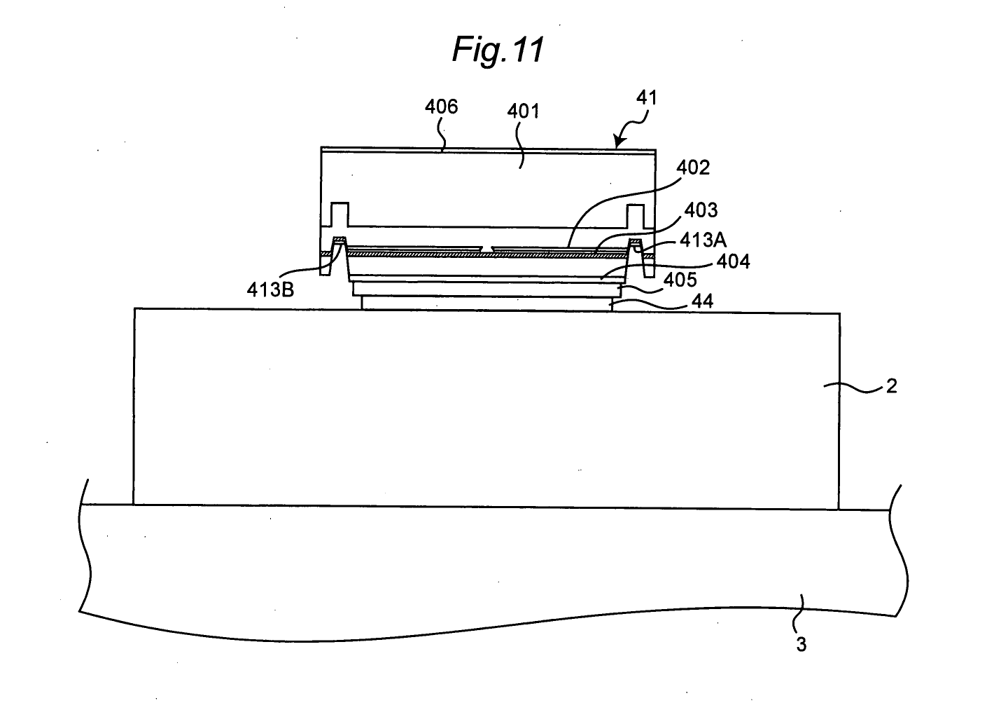

FIG. 11 is a schematic front view of a nitride semiconductor laser device according to a third embodiment of the invention. In FIG. 11, the same component members as those of the first embodiment shown in FIG. 2 are designated by the same reference numerals as those of FIG. 2 and their description is omitted.

This nitride semiconductor laser device includes a nitride semiconductor laser element 41 mounted on the surface of the submount 2 with solder 44. It is noted that the solder 44 is an example of the conductive adhesive and differs from the solder 4 of the first embodiment only in its shape.

The nitride semiconductor laser element 41 is not a ridge stripe type one, but an internal constriction structure type one. More specifically, the nitride semiconductor laser element 41 has an n-GaN substrate 401, a current constriction layer 402, an active layer 403, a p-contact electrode 404, a p-side electrode 405, and an n-side electrode 406. Then, in the nitride semiconductor laser element 41, nitride semiconductor is exposed from its side faces. Also, crack preventing grooves 413A, 413B are formed on an upper surface (a surface on a submount 2 side) of the nitride semiconductor laser element 41.

According to the nitride semiconductor laser device constructed as described above, mounting of the nitride semiconductor laser element 41 is carried out in the same manner as in the first embodiment, and the nitride semiconductor laser device includes the nitride semiconductor laser element 41. Therefore, the element resistance can be decreased, and effects advantageous for stable operations at high power can be obtained.

### Fourth Embodiment

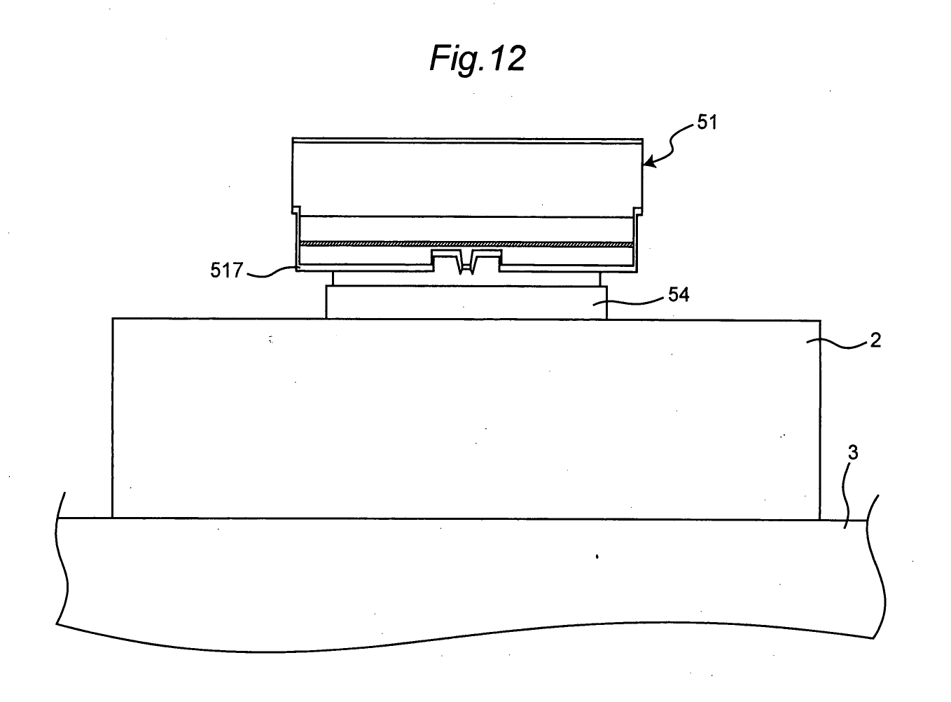

FIG. 12 is a schematic front view of a nitride semiconductor laser device according to a fourth embodiment of the invention. In FIG. 12, the same component members as those of the first embodiment shown in FIG. 2 are designated by the same reference numerals as those of FIG. 2 and their description is omitted.

The nitride semiconductor laser device includes a nitride semiconductor laser element 51 mounted on the surface of the submount 2 with Ag solder 54. The Ag solder 54 has a thermal conductivity of 400 W/mK, better than Au, so being formed 5 thick, thicker than the solder 4 that is 2 μm thick. As a result, the thermal resistance can be decreased. It is noted that the solder 54 is an example of the conductive adhesive.

The nitride semiconductor laser element 51, in which no crack preventing grooves are formed, has constituent layers similar to those of the nitride semiconductor laser element 31 of the second embodiment. Also, the nitride semiconductor laser element 51 has a dielectric film 517, and the dielectric film 517 covers part of side faces of the nitride semiconductor laser element 31. It is noted that the dielectric film 517 is an example of the dielectric.

According to the nitride semiconductor laser device constructed as described above, since the nitride semiconductor laser element 51 having no crack preventing grooves formed therein is included, the forward voltage can be reduced. Moreover, to an extent corresponding to the non-formation of crack preventing grooves, the number of manufacturing steps is lessened so that a cost reduction effect can be obtained.

The dielectric film 517 contains at least one of zirconia, AlN, AlON, diamond, DLC and SiO₂.

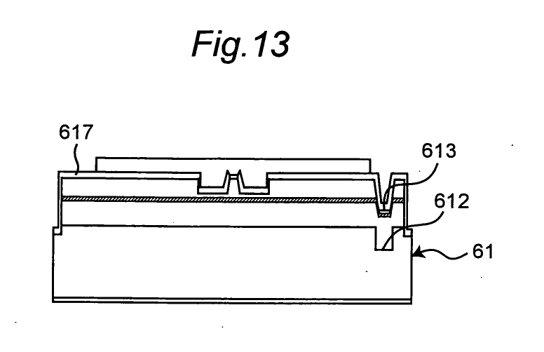

Although the nitride semiconductor laser element 51 in which no crack preventing grooves are formed is used in this fourth embodiment, yet a nitride semiconductor laser element 61 shown in FIG. 13 may also be used.

The nitride semiconductor laser element 61 has crack preventing grooves 612, 613 at a side portion only on one side of a ridge portion. This crack preventing groove 612 is covered with a dielectric film 617 containing at least one of zirconia, AlN, AlON, diamond, DLC and SiO₂. It is noted that the dielectric film 617 is an example of the dielectric.

### Fifth Embodiment

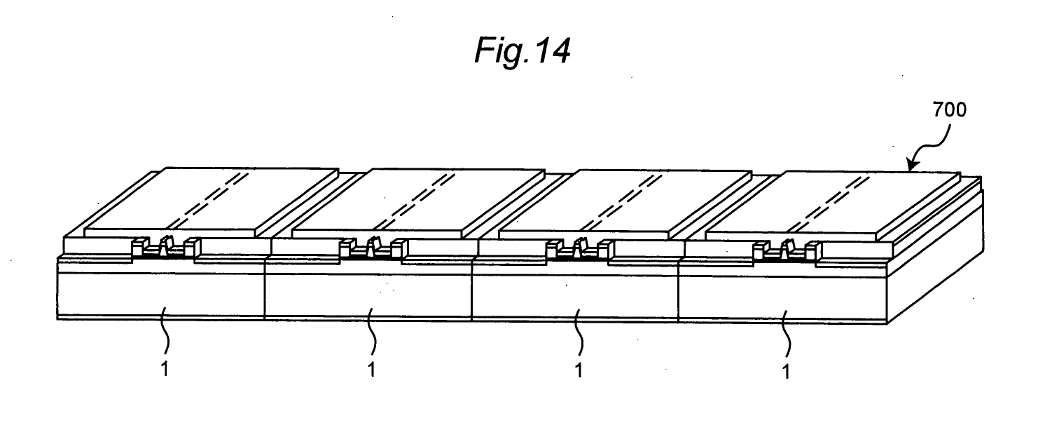

A nitride semiconductor laser device according to a fifth embodiment of the invention includes a light emitting section 700 shown in FIG. 14. This light emitting section 700 includes the nitride semiconductor laser element 1 of the first embodiment in plurality.

The plurality of nitride semiconductor laser elements 1 are placed in array. Therefore, since those nitride semiconductor laser elements emit same quantity of light, the intensity of light emitted from one ridge stripe can be lowered, so that injection power per unit area is lowered, leading to a rise of the thermal saturation level. Thus, it becomes possible to output higher optical power.

When ten ridges each having a ridge width of 7 μm were formed at 200 μm ridge intervals in a lateral width of mm with a resonator length of 800 μm, the nitride semiconductor laser device did not show thermal saturation until 6 W was reached.

Hereinabove, embodiments of the present invention have been concretely described. However, the invention is not limited to the above-described embodiments, and various modifications and changes may be made based on technical concepts of the invention. For example, numerical values, materials, structures, processes and the like listed in the embodiments should be construed as examples only and are not limitative.

In more detail, although AlON is formed by ECR sputtering process in the above embodiments, yet parallel-plate sputtering process or the like may also be used. Although the n-electrode and the p-contact electrode are formed by EB vapor deposition process, yet these may be formed alternatively by sputtering process or resistor vapor deposition process. Although the p-electrode is formed by sputtering process, it may be formed alternatively by vapor deposition process. Although the thick film of Au is formed by electroless plating process, it may be formed alternatively by electroplating process, sputtering process or vapor deposition process. Although Pd is used as the material of the p-contact electrode, Ni or other metals may be used. Besides, although Mo/Au is used for the p-electrode, yet Au only, or a multilayered structure of Pt/Ti/Au or the like may be used. Although the semiconductor layers are stacked by MOCVD process, yet MBE process may be used.

For the present invention, the crack preventing grooves do not necessarily need to be formed in plural quantity for each element and, if necessary, only one crack preventing groove is also allowable.

The above-described first to fifth embodiments may be combined in various combinations, as required, to provide one embodiment of the invention. Also, such modifications as shown in the first embodiment may be made on the second to fifth embodiments.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### Citation List

Patent Literature

Patent Literature: JP 2007-180522 A

1. A semiconductor laser device comprising:
a mount member; and
a nitride semiconductor laser element which is mounted on a surface of the mount member with a conductive adhesive so that a nitride semiconductor is exposed from a side face thereof, wherein
the conductive adhesive is positioned between the mount member and the nitride semiconductor laser element and smaller in width than the nitride semiconductor laser element.

2. The semiconductor laser device as claimed in claim 1, wherein
a crack preventing groove is formed on a mount member-side surface of the nitride semiconductor laser element, and
the conductive adhesive is opposed to a region other than the crack preventing groove on the mount member-side surface of the nitride semiconductor laser element.

3. The semiconductor laser device as claimed in claim 1, wherein
part of the side face of the nitride semiconductor laser element is covered with a dielectric.

4. The semiconductor laser device as claimed in claim 2, wherein
the crack preventing groove is covered with a dielectric.

5. The semiconductor laser device as claimed in claim 3, wherein
the dielectric contains at least one of zirconia, AlN, AlON, diamond, DLC and SiO₂.

6. The semiconductor laser device as claimed in claim 1, wherein
the nitride semiconductor laser element is placed on the mount member in such a manner that a light-emitting end face protrudes from a region on the mount member.

7. The semiconductor laser device as claimed in claim 6, wherein
a distance between a plane containing the light-emitting end face of the nitride semiconductor laser element and a plane containing the end face of the mount member on the light-emitting end face-side is set to within a range from 100 nm to 100 μm.

8. The semiconductor laser device as claimed in claim 1, wherein
the mount member is a submount whose principal material is AlN, diamond, SiC or Cu.

9. The semiconductor laser device as claimed in claim 1, wherein
the conductive adhesive is Au—Sn solder, Sn—Ag—Cu solder or Ag solder.

10. The semiconductor laser device as claimed in claim 1, wherein
the mount member is a stem.

11. The semiconductor laser device as claimed in claim 1, wherein
the nitride semiconductor laser element includes a ridge portion, and
terrace portions formed on both sides of the ridge portion and generally equal in height to the ridge portion.

12. The semiconductor laser device as claimed in claim 1, wherein
the nitride semiconductor laser element has an electrode electrically connected to the mount member via the conductive adhesive, and
the electrode has a thickness within a range from 1.5 μm to 1100 μm.

13. The semiconductor laser device as claimed in claim 12, wherein
the electrode contains at least one of Au, Ag and Cu.

14. The semiconductor laser device as claimed in claim 1, wherein
a plurality of the nitride semiconductor laser elements are included in the semiconductor laser device.

15. A method for manufacturing a semiconductor laser device comprising:
a formation step for forming a conductive adhesive on a surface of a mount member; and
a mounting step for placing a nitride semiconductor laser element on the conductive adhesive so that a nitride semiconductor is exposed from a side face of the nitride semiconductor laser element, whereby the nitride semiconductor laser element is mounted on the surface of the mount member, wherein
a width to which the conductive adhesive is formed in the formation step is a width which is so predetermined that a width of the conductive adhesive after the mounting step becomes smaller than a width of the nitride semiconductor laser element.

16. The method for manufacturing a semiconductor laser device as claimed in claim 15, wherein
the nitride semiconductor laser element has an electrode electrically connected to the mount member via the conductive adhesive, and
the width of the conductive adhesive in the formation step is 50% or more of a width of the electrode and smaller than the width of the nitride semiconductor laser element at least by an extent corresponding to a thickness of the conductive adhesive.
